(19) United States
(12) Patent Application Publication
(10) Pub. No.: US 2009/0020324 A1
(43) Pub. Date: Jan. 22, 2009

(54) Wired circuit board

(75) Inventors: Katsutoshi Kamei, Osaka (JP); Visit Thaveeprungsriporn, Osaka (JP); Kazuya Nakamura, Osaka (JP)

Correspondence Address: AKERMAN SENTERFITT, 801 PENNSYLVANIA AVENUE N.W., SUITE 600, WASHINGTON, DC, 20004, US

(73) Assignee: Nitto Denko Corporation, Osaka (JP)

(21) Appl. No.: 12/219,208

(22) Filed: Jul. 17, 2008

Related U.S. Application Data
(60) Provisional application No. 60/935,319, filed on Aug. 6, 2007.

(30) Foreign Application Priority Data
Jul. 18, 2007 (JP) 2007-187087

(51) Int. Cl. H05K 1/09

(52) U.S. Cl. 174/257

(57) ABSTRACT

A wired circuit board comprises a metal supporting board, a metal foil formed on the metal supporting board, a first protecting layer formed on the surface of the metal foil, the first protecting layer is made of tin or a tin alloy, a first insulating layer formed on the metal supporting board to cover the first protecting layer, a conductive pattern formed on the insulating layer, and a second protecting layer formed on the surface of the conductive pattern, the second protecting layer is made of tin or a tin alloy.

### CROSS-REFERENCE TO RELATED APPLICATIONS

This patent application claims the benefit of U.S. Provisional Application No. 60/935,319, filed on Aug. 6, 2007, and claims priority from Japanese Patent Application No. 2007-187087, filed on Jul. 18, 2007, the contents of which are herein incorporated by reference in their entirety.

### BACKGROUND OF THE INVENTION

1. Field of the Invention

The present invention relates to a wired circuit board, and, more particularly, to a wired circuit board preferably used as a suspension board with circuit.

2. Description of the Related Art

There has been conventionally known a suspension board with circuit prepared by successively forming an insulating layer made of resin and a conductive pattern made of copper on a metal supporting board made of stainless steel, and is employed for a hard disk drive or the like with a magnetic head.

In such a suspension board with circuit, transmission loss increases in the conductive pattern due to the metal supporting board made of stainless steel. In order to reduce the transmission loss, therefore, it is proposed that a lower conductor made of copper or a copper alloy mainly composed of copper is provided on a suspension, and an insulating layer, a record-side conductor and a reproduction-side conductor are successively formed on the lower conductor (see, e.g., Japanese Unexamined Patent Publication No. 2005-11387).

### SUMMARY OF THE INVENTION

In a suspension board with circuit, a magnetic head carrying section generally supports a magnetic head, so that the magnetic head maintains a predetermined angle with respect to a magnetic disk of a hard disk drive. More specifically, the magnetic head carrying section is folded along the width direction orthogonal to the longitudinal direction in the suspension board with circuit, and the magnetic head is maintained at the predetermined angle with respect to the magnetic disk according to the folding angle.

In the suspension board with circuit according to Japanese Unexamined Patent Publication No. 2005-11387, however, the magnetic head carrying section which was folded once is easily restored due to the formation of the lower conductor, whereby it is difficult to maintain the angle of the magnetic head carrying section.

An object of the present invention is to provide a wired circuit board capable of reducing transmission loss in a conductive pattern with a simple layer structure and excellent in shape retention after folding.

A wired circuit board according to the present invention comprises a metal supporting board, a metal foil formed on the metal supporting board, a first protective layer, made of tin or a tin alloy, formed on the surface of the metal foil, a first insulating layer formed on the metal supporting board to cover the first protective layer, a conductive pattern formed on the insulating layer and a second protective layer, made of tin or a tin alloy, formed on the surface of the conductive pattern.

In the wired circuit board according to the present invention, it is preferable that the metal foil and the conductive pattern are made of copper, and the first protective layer and the second protective layer are made of a tin-copper alloy prepared by diffusing tin into copper.

In the wired circuit board according to the present invention, it is preferable that the thickness of each of the first protective layer and the second protective layer is not less than 0.05 μm.

It is preferable that the wired circuit board according to the present invention further comprises a second insulating layer interposed between the metal supporting board and the metal foil.

It is preferable that the wired circuit board according to the present invention is employed as a suspension board with circuit.

In the wired circuit board according to the present invention, it is possible to reduce transmission loss due to the simple layer structure having the metal foil interposed between the metal supporting board and the conductive pattern, while shape retention after folding can be improved due to the first protective layer and the second protective layer made of tin or a tin alloy.

Therefore, the position of an electronic component can be reliably maintained after folding.

Further, occurrence of such an ion migration phenomenon that the metal of the metal foil migrates to the insulating layer can be reliably prevented due to the first protective layer interposed between the insulating layer and the metal foil.

### BRIEF DESCRIPTION OF THE DRAWING

FIG. 1 is a plan view of a suspension board with circuit according to an embodiment of the inventive wired circuit board.

FIG. 2 is a sectional view along a folding section in the suspension board with circuit shown in FIG. 1.

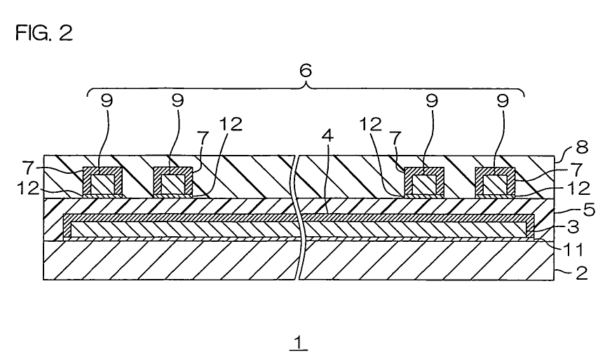

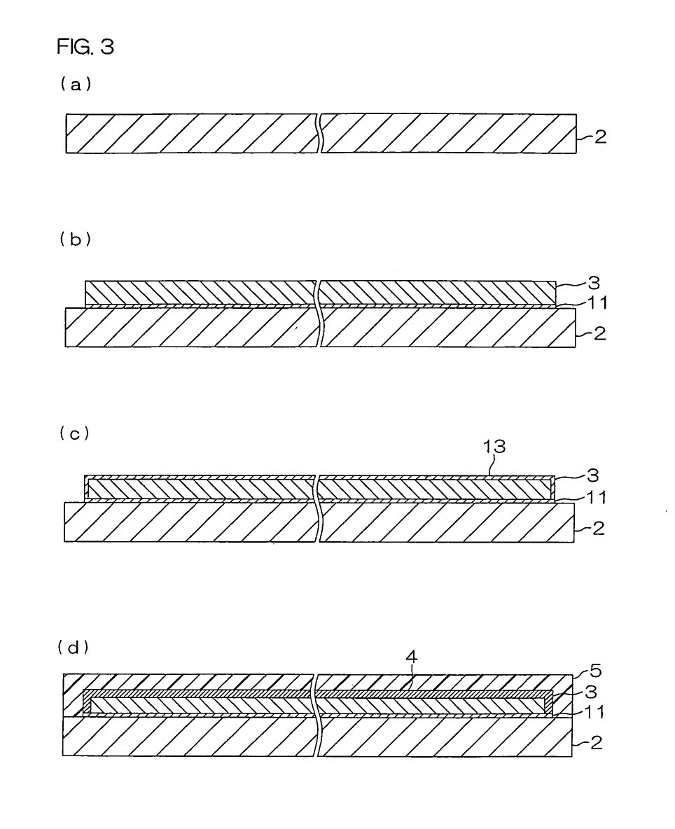

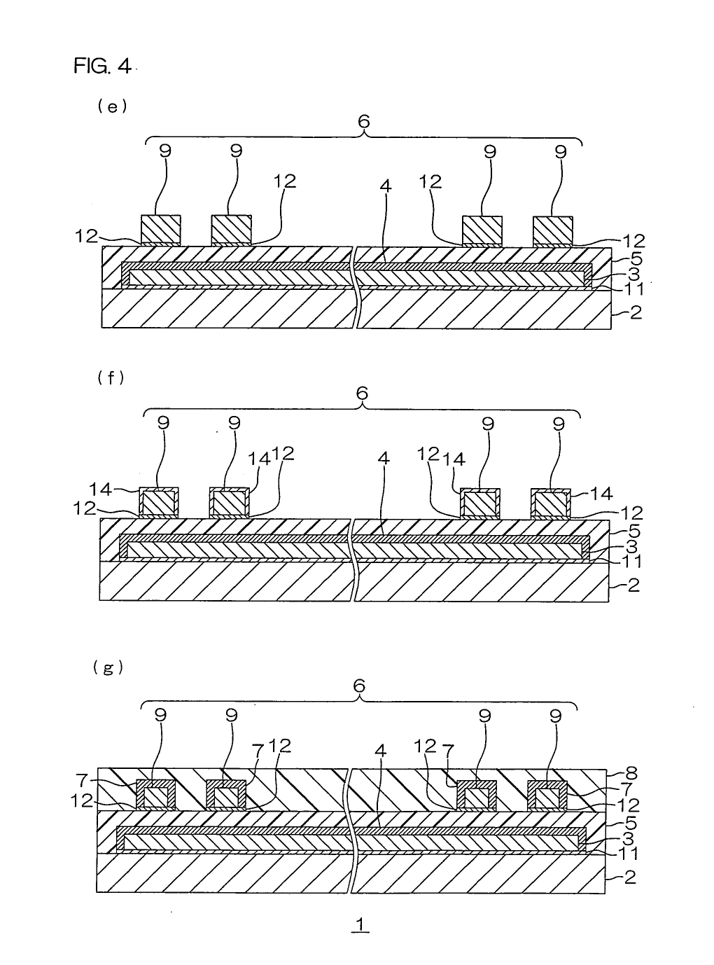

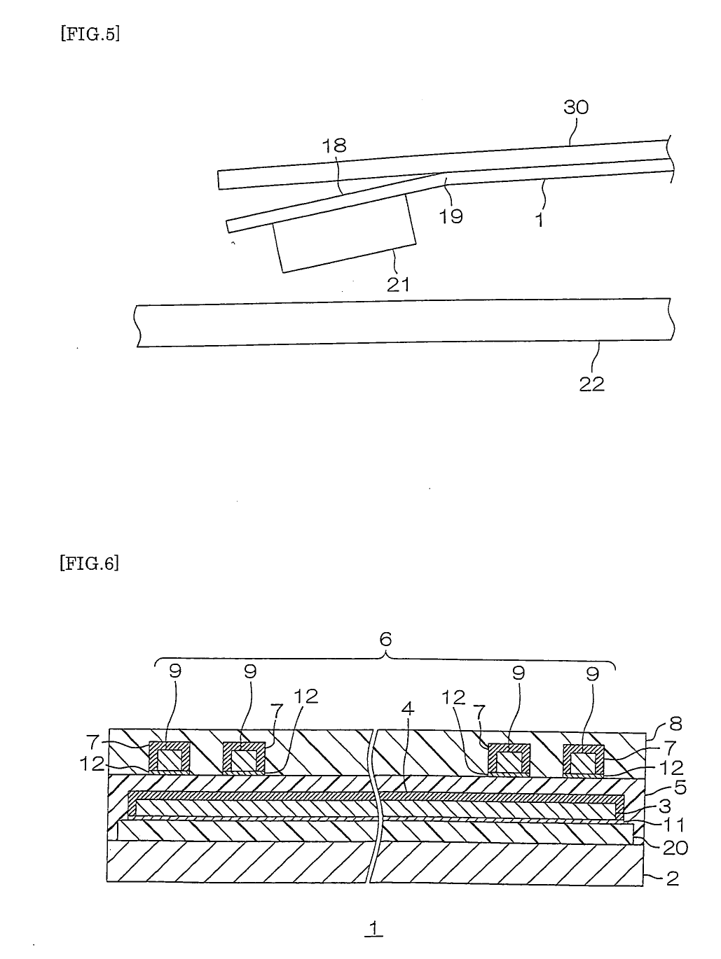

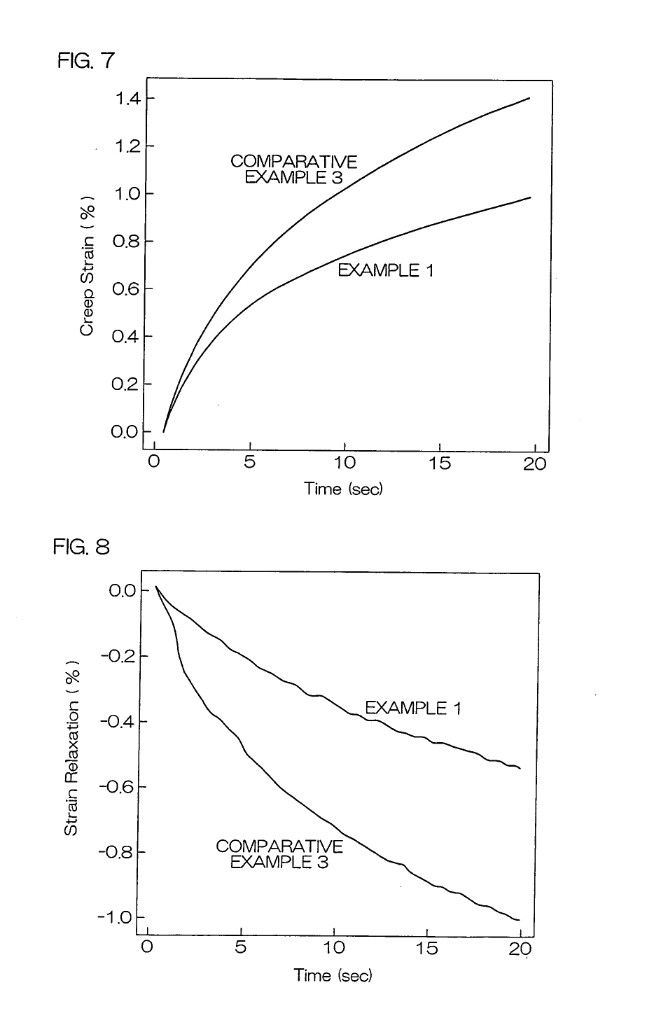

FIG. 3 is a manufacturing process view showing a method for manufacturing the suspension board with circuit shown in FIG. 2,
(a) showing the step of preparing a metal supporting board,
(b) showing the step of forming a metal foil on the metal supporting board,
(c) showing the step of forming a first tin layer on the surface of the metal foil, and
(d) showing the step of forming an insulating base layer and a first protective layer.

FIG. 4 is a manufacturing process view showing the method for manufacturing the suspension board with circuit shown in FIG. 2 subsequently to FIG. 3,
(e) showing the step of forming a conductive pattern on the insulating base layer,
(f) showing the step of forming a second tin layer on the surface of the conductive pattern, and
(g) showing the step of forming an insulating base layer and a second protective layer.

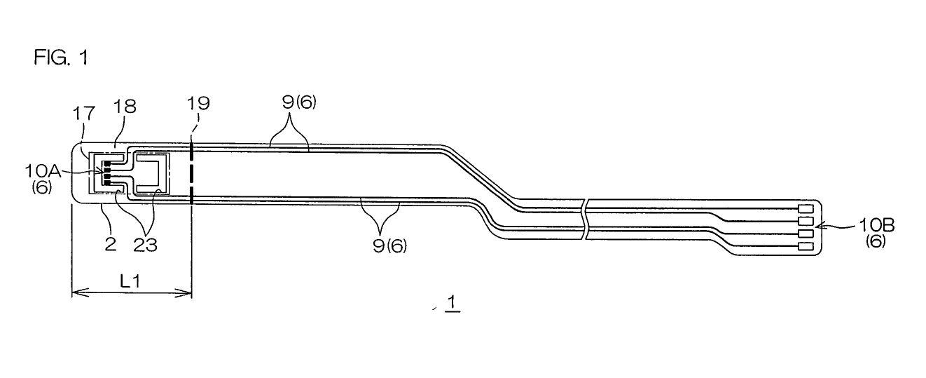

FIG. 5 is a sectional view along the longitudinal direction of the suspension board with circuit shown in FIG. 1, illustrating the suspension board with circuit in a state mounted on a hard disk drive.

FIG. 6 is a sectional view along a folding section in a suspension board with circuit according to another embodiment of the inventive wired circuit board.

FIG. 7 is a chart showing creep strains in suspension boards with circuit according to EXAMPLE 1 and COMPARATIVE EXAMPLE 3.

FIG. 8 is a chart showing strain relaxations in suspension boards with circuit according to EXAMPLE 1 and COMPARATIVE EXAMPLE 3.

### DETAILED DESCRIPTION OF THE INVENTION

FIG. 1 is a plan view of a suspension board with circuit according to an embodiment of the inventive wired circuit board, FIG. 2 is a sectional view along a later-described folding section in the suspension board with circuit shown in FIG. 1, and FIG. 5 is a sectional view along the longitudinal direction of the suspension board with circuit, illustrating the suspension board with circuit shown in FIG. 1 in a state mounted on a hard disk drive.

In FIG. 1, a metal foil 3, a first protective layer 4, an insulating base layer 5, a second protective layer 7 and an insulating cover layer 8 described later are omitted, in order to clearly show the relative arrangement of a conductive pattern 6 with respect to a metal supporting board 2.

Referring to FIGS. 1 and 5, this suspension board with circuit 1 is mounted on the hard disk drive for packaging a magnetic head 21 and supporting this magnetic head 21 to oppose to a magnetic disk 22, and provided with the conductive pattern 6 for electrically connecting the magnetic head 21 with an unshown read/write board (external circuit).

The conductive pattern 6 integrally and continuously includes magnetic-head-side connecting terminal portions 10A, external-side connecting terminal portions 10B and a plurality of wires 9 for connecting the magnetic-head-side connecting terminal portions 10A and the external-side connecting terminal portions 10B with one another.

The plurality of (e.g., four) wires 9 are provided along the longitudinal direction of the metal supporting board 2, and parallelly opposed to one another at intervals in the direction (hereinafter simply referred to as the width direction) orthogonal to the longitudinal direction of the metal supporting board 2. Each wire 9 is a read wire for reading data from the magnetic disk 22 or a write wire for writing data in the magnetic disk 22, and a read signal is input in the read wire, while a write signal is input in the write wire.

The plurality of magnetic-head-side connecting terminal portions 10A are arranged on a longitudinal end (hereinafter referred to as the forward end) of the metal supporting board 2, and parallelly provided as wide lands so that the forward ends of the wires 9 are connected thereto respectively. Terminal portions (not shown) of the magnetic head 21 are connected to the magnetic-head-side connecting terminal portions 10A.

The plurality of external-side connecting terminal portions 10B are arranged on another longitudinal end (hereinafter referred to as the rear end) of the metal supporting board 2, and parallelly provided as wide lands so that the rear ends of the wires 9 are connected thereto respectively. Terminal portions (not shown) of the read/write board are connected to the external-side connecting terminal portions 10B.

A gimbal section 18 for packaging the magnetic head 21 is provided on the forward end of the metal supporting board 2. The gimbal section 18 is provided with notches 23 holding the magnetic-head-side connecting terminal portions 10A therebetween in the longitudinal direction.

In the gimbal section 18, a region, including the notches 23, slightly larger than the notches 23 defines a packaging region 17 for packaging the magnetic head 21, as shown by phantom lines in FIG. 1.

On the forward end of this suspension board with circuit 1, a linear portion arranged at the back of the gimbal section 18 along the width direction defines a folding section 19.

The position of the folding section 19 is properly selected in response to the size of the magnetic head 21 and the like, and the length L1 between the folding section 19 and the forward edge of the metal supporting board 2 is set to 5 to 7 mm, for example.

This suspension board with circuit 1 includes the metal supporting board 2, a first metal thin film 11 formed on the metal supporting board 2, the metal foil 3 formed on the first metal thin film 11, the first protective layer 4 formed on the surface of the meal foil 3 and the insulating base layer 5 serving as a first insulating layer formed on the metal supporting board 2 to cover the first protective layer 4. The suspension board with circuit 1 further includes a second metal thin film 12 formed on the insulating base layer 5, the conductive pattern 6 formed on the second metal thin film 12, the second protective layer 7 formed on the surface of the conductive pattern 6 and the insulating cover layer 8 formed on the insulating base layer 5 to cover the second protective layer 7.

The metal supporting board 2 is formed by a flat metal foil or metal thin plate corresponding to the outer shape of the suspension board with circuit 1. Examples of a metal used to form the metal supporting board 2 include stainless steel and a 42-alloy, and stainless steel is preferably used. The thickness of the metal supporting board 2 is in the range of, e.g., 15 to 30 μm, or preferably 20 to 25 μm.

The first metal thin film 11 is formed in a pattern on the surface of the metal supporting board 2, to oppose to the portion where the metal foil 3 is formed. More specifically, the first metal thin film 11 is formed between the outermost wires 9 in the width direction among the plurality of wires 9 arranged at intervals along the width direction, to oppose to these wires 9 in the width direction and to be smaller in width than the metal supporting board 2. The first metal thin film 11 is interposed between the metal foil 3 and the metal supporting board 2.

Examples of a metal used to form the first metal thin film 11 include copper, chromium, gold, silver, platinum, nickel, titanium, silicon, manganese, zirconium, an alloy thereof and an oxide thereof. Preferably, copper, chromium, nickel or an alloy thereof is used. The first metal thin film 11 can also be formed by a plurality of layers. The thickness of the first metal thin film 11 is in the range of, e.g., 0.01 to 1 μm, or preferably 0.01 to 0.1 μm.

The metal foil 3 is formed in a pattern on the surface of the first metal thin film 11, to oppose to at least the portion where the conductive pattern 6 is formed. More specifically, the metal foil 3 is formed on the entire surface of the first metal thin film 11.

Examples of a metal used to form the metal foil 3 include copper, nickel, gold, solder and an alloy thereof, and copper is preferably used. The thickness of the metal foil 3 is in the range of, e.g., 2 to 5 μm, or preferably 2 to 4 μm.

The first protective layer 4 is formed on the surface of the metal foil 3, to cover the metal foil 3. More specifically, the first protective layer 4 is formed on the upper surface, both width-directional side surfaces and both longitudinal side surfaces of the metal foil 3 and both width-directional side surfaces and both longitudinal side surfaces of the first metal thin film 11, to erode and cover these surfaces. This first protective layer 4 is interposed between the metal foil 3 and the first metal thin film 11, and the insulating base layer 5.

Examples of a metal used to form the first protective layer 4 include tin and a tin alloy, and the tin alloy is preferably used. When the metal foil 3 is made of copper, the first protective layer 4 is preferably made of a tin-copper alloy.

The thickness of the first protective layer 4 is, e.g., not less than 0.05 μm, or preferably not less than 0.2 μm, and generally not more than 1.0 μm, or preferably not more than 0.5 μm. If the thickness of the first protective layer 4 is out of the aforementioned range, shape retention after folding may be reduced. The thickness of the first protective layer 4 can be measured by TOF-SIMS.

The insulating base layer 5 is formed on the metal supporting board 2, to cover the first protective layer 4.

Examples of an insulator used to form the insulating base layer 5 include synthetic resin such as polyimide, polyether nitrile, polyether sulfone, polyethylene terephthalate, polyethylene naphthalate and polyvinyl chloride. Among these, photosensitive synthetic resin is preferably used, and photosensitive polyimide is more preferably used. The thickness of the insulating base layer 5 is in the range of, e.g., 1 to 10 μm, or preferably 1 to 5 μm.

The second metal thin film 12 is formed in a pattern on the surface of the insulating base layer 5, to oppose to the portion where the conductive pattern 6 is formed. This second metal thin film 12 is interposed between the conductive pattern 6 and the insulating base layer 5.

A metal similar to that described above with reference to the first metal thin film 11 is used to form the second metal thin film 12. Preferably, copper, chromium, nickel or an alloy thereof is preferably used. The second metal thin film 12 can also be formed by a plurality of layers. The thickness of the second metal thin film 12 is in the range of, e.g., 0.01 to 1 μm, or preferably 0.01 to 0.1 μm.

The conductive pattern 6 is formed as a wired circuit pattern composed of the wires 9 and the magnetic-head-side connecting terminal portions 10A and the external-side connecting terminal portions 10B provided on both longitudinal ends of the wires 9, on the surface of the second metal thin film 12 and above the insulating base layer 5.

Examples of a conductor used to form the conductive pattern 6 include metals such as copper, nickel, gold and solder, or an alloy thereof. Among these, copper is preferably used. The thickness of the conductive pattern 6 is in the range of, e.g., 5 to 20 μm, or preferably 7 to 15 μm. The width of each wire 9 is in the range of, e.g., 15 to 100 μm, or preferably 20 to 50 μm.

The second protective layer 7 is formed on the surface of the conductive pattern 6, to cover the conductive pattern 6. More specifically, the second protective layer 7 is formed on the upper surfaces (excluding the upper surfaces of the terminal portions 10) and both width-directional side surfaces of the wires 9 of the conductive pattern 6 and both width-directional side surfaces of the second metal thin film 12, to erode and cover these surfaces. This second protective layer 7 is interposed between the conductive pattern 6 and the second metal thin film 12, and the insulating cover layer 8.

Examples of a metal used to the second protective layer 7 include tin and a tin alloy, and the tin alloy is preferably used. If the conductive pattern 6 is made of copper, the second protective layer 7 is preferably made of a tin-copper alloy.

The thickness of the second protective layer 7 is, e.g., not less than 0.05 μm, or preferably not less than 0.2 μm, and generally not more than 1.0 μm, or preferably not more than 0.5 μm. If the thickness of the second protective layer 7 is out of the aforementioned range, shape retention after folding may be reduced. The thickness of the second protective layer 7 can be measured by TOF-SIMS.

The insulating cover layer 8 is formed on the insulating base layer 5, to cover the second protective layer 7. More specifically, the insulating cover layer 8 is formed on the entire surface of the insulating base layer 5 in the width direction.

An insulator similar to that described above with reference to the insulating base layer 5 is used to form the insulating cover layer 8. Photosensitive synthetic resin is preferably used, or photosensitive polyimide is more preferably used. The thickness of the insulating cover layer 8 is in the range of, e.g., 2 to 10 μm, or preferably 3 to 6 μm. The insulating cover layer 8 is so opened as to expose the terminal portions 10 of the conductive pattern 6, though not shown in FIG. 2.

A method for manufacturing this suspension board with circuit 1 is now described with reference to FIGS. 3 and 4.

First, as shown in FIG. 3(a), the metal supporting board 2 is prepared according to this method.

Then, as shown in FIG. 3(b), the first metal thin film 11 and the metal foil 3 are formed on the metal supporting board 2 according to this method.

The first metal thin film 11 and the metal foil 3 are formed by, e.g., a patterning method such as an additive method or a subtractive method. Preferably, the first metal thin film 11 and the metal foil 3 are formed by the additive method.

In the additive method, the first metal thin film 11 (seed film) is first formed on the entire surface of the metal supporting board 2. The first metal thin film 11 is formed by sputtering, electrolytic plating or electroless plating, for example.

Then, a dry film resist is provided on the surface of the first metal thin film 11 and exposed to light and developed, to form an unshown plating resist in a pattern reverse to the aforementioned pattern. Then, the metal foil 3 is formed on the surface of the first metal thin film 11 exposed through the plating resist in the aforementioned pattern by plating. Then, the plating resist and the portion of the first metal thin film 11 where the plating resist is formed are removed by etching or the like. The metal foil 3 is formed preferably by electrolytic plating, or more preferably by electrolytic copper plating.

Then, as shown in FIG. 3(c), a first tin layer 13 is formed on the surface of the metal foil 3 according to this method.

In order to form the first tin layer 13 tin plating, for example, or preferably electroless tin plating is used. When the metal foil 3 is made of copper, the first tin layer 13 is so formed in this electroless tin plating that the surface of the metal foil 3 is etched, more specifically the upper surface and side surfaces of the metal foil 3 are eroded by substitution between copper and tin.

The thickness of the first tin layer 13 is, e.g., not less than 0.05 μm, or preferably not less than 0.2 μm, and generally not more than 1.0 μm, or preferably not more than 0.5 μm. If the thickness of the first tin layer 13 is out of the aforementioned range, it may not be possible to set the thickness of the first protective layer 4 in the aforementioned range.

Then, as shown in FIG. 3(d), the insulating base layer 5 as well as the first protective layer 4 are formed according to this method.

In order to form the insulating base insulating layer 5, a varnish of an insulator, such as a varnish of synthetic resin, for example, used to form the insulating base layer 5 is coated, dried and cured as necessary. More specifically, a varnish of photosensitive resin, preferably a varnish of photosensitive polyamic acid resin is coated, dried, thereafter exposed to light and developed, and thereafter cured for forming the insulating base layer 5 in the aforementioned pattern.

The first protective layer 4 is formed through the heat treatment for drying or curing the suspension board with circuit 1 coated with the aforementioned varnish in the manufacturing process.

The conditions for this heat treatment are set to the range of, e.g., 60 to 250° C., or preferably 80 to 200° C., for the period of, e.g., 60 to 300 minutes, or preferably 120 to 300 minutes in drying, and set to the range of, e.g., 300 to 450° C., or preferably 350 to 400° C., for the period of, e.g., 60 to 300 minutes, or preferably 120 to 300 minutes under decompression, for example, in curing. The heat treatment can also be performed under an oxygen-containing atmosphere such as an air atmosphere or under an inactive gas atmosphere such as a nitrogen atmosphere, for example, preferably under the inert gas atmosphere.

Thus, tin is diffused into the metal forming the metal foil 3 and the metal forming the metal foil 3 is diffused into tin, thereby forming the first protective layer 4. Preferably, when the metal foil 3 is made of copper, tin is diffused into copper and copper is diffused into tin, thereby forming the first protective layer 4 made of a tin-copper alloy.

In this diffusion of tin, the part of tin forming the first tin layer 13 formed on the upper surface of the metal foil 3 is diffused downward while the part of tin forming the first tin layer 13 formed on both width-directional side surfaces and both longitudinal side surfaces of the metal foil 3 is diffused inward along the width direction and the longitudinal direction, whereby the first protective layer 4 made of a tin alloy is formed with a thickness larger than that of the first tin layer 13 in the unheated state.

Due to this diffusion of tin, tin forming the first tin layer 13 is substituted by the tin alloy, and the first tin layer 13 generally disappears.

In the first protective layer 4 made of the tin alloy, the tin concentration, i.e., the atomic ratio at which tin is diffused is calculated from the thickness of the first tin layer 13 in the unheated state and that of the first protective layer 4 in the heated state. The tin concentration is in the range of, e.g., 1 to 60 atomic %, or preferably 20 to 30 atomic % with respect to the tin alloy.

In the first protective layer 4 made of the tin alloy, tin is diffused with distributions in the thickness direction, the width direction and the longitudinal direction so that the tin concentration is at the maximum on the outermost layer and gradually reduced from the outermost layer downward in the thickness direction and inward in the width direction and the longitudinal direction.

Then, as shown in FIG. 4(e), the second metal thin film 12 and the conductive pattern 6 are formed on the insulating base layer 5 in the aforementioned wired circuit pattern according to this method.

The conductive pattern 6 is formed by, e.g., a patterning method such as the additive method or the subtractive method. Preferably, the conductive pattern 6 is formed by the additive method.

In the additive method, the second metal thin film 12 (seed film) is first formed on the entire surface of the insulating base layer 5. This second metal thin film 12 is formed by sputtering, electrolytic plating or electroless plating.

Then, a dry film resist is provided on the surface of the second metal thin film 12 and exposed to light and developed, to form an unshown plating resist in a pattern reverse to the wired circuit pattern. Then, the conductive-pattern 6 is formed on the surface of the second metal thin film 12 exposed through the plating resist in the wired circuit pattern by plating, and the plating resist and the portion of the second metal thin film 12 on which the plating resist is formed are removed by etching or the like. The conductive pattern 6 is formed preferably by electrolytic plating, more preferably by electrolytic copper plating.

Then, as shown in FIG. 4(f), a second tin layer 14 is formed on the surface of the conductive pattern 6 according to this method.

The second tin layer 14 is formed by a method similar to the aforementioned one for forming the first tin layer 13. The thickness of the second tin layer 14 is, e.g., not less than 0.05 μm, or preferably not less than 0.2 μm, and generally not more than 1.0 μm, or preferably not more than 0.5 μm. If the thickness of the second tin layer 14 is out of the aforementioned range, it may be not possible to set the thickness of the second protective layer 7 in the aforementioned range.

Then, as shown in FIG. 4(g), the insulating cover layer 8 as well as the second protective layer 7 are formed according to this method.

In order to form the insulating cover layer 8, a varnish of an insulator, such as a varnish of synthetic resin, for example, used to form the insulating cover layer 8 is coated, dried and cured as necessary. More specifically, a varnish of photosensitive synthetic resin, preferably a varnish of photosensitive polyamic acid resin is coated, dried, exposed to light and developed, and thereafter cured for forming the insulating cover layer 8 in the aforementioned pattern.

The second protective layer 7 is formed through the heat treatment for drying or curing the suspension board with circuit 1 coated with the aforementioned varnish in the manufacturing process.

The conditions for this heat treatment are set to the range of, e.g., 60 to 250° C., or preferably 80 to 200° C., for the period of, e.g., 60 to 300 minutes, or preferably 120 to 300 minutes in drying, and set to the range of, e.g., 300 to 450° C., or preferably 350 to 400° C., for the period of, e.g., 60 to 300 minutes, or preferably 120 to 300 minutes under decompression, for example, in curing. The suspension board with circuit 1 can also be heated, e.g., under an oxygen-containing atmosphere such as an air atmosphere or under an inactive gas atmosphere such as a nitrogen atmosphere, preferably under the inert gas atmosphere.

Thus, tin is diffused into the conductor forming the conductive pattern 6 and the conductor forming the conductive pattern 6 is diffused into tin, thereby forming the second protective layer 7. Preferably, when the conductive pattern 6 is made of copper, tin is diffused into copper and copper is diffused into tin, thereby forming the second protective layer 7 made of a tin-copper alloy.

In this diffusion of tin, the part of tin forming the second tin layer 14 formed on the upper surface of the conductive pattern 6 is diffused downward while the part of tin forming the second tin layer 14 formed on both width-directional side surfaces and both longitudinal side surfaces of the conductive pattern 6 is diffused inward along the width direction and the longitudinal direction, whereby the second protective layer 7 made of a tin alloy is formed with a thickness larger than that of the second tin layer 14 in the unheated state.

Due to this diffusion of tin, tin forming the second tin layer 14 is substituted by the tin alloy, and the second tin layer 14 generally disappears.

In the second protective layer 7 made of the tin alloy, the tin concentration, i.e., the atomic ratio at which tin is diffused is in the range of, e.g., 1 to 60 atomic %, or preferably 20 to 30 atomic % with respect to the tin alloy.

In the second protective layer 7 made of the tin alloy, tin is diffused with distributions in the thickness direction and the width direction so that the tin concentration is at the maximum on the outermost layer and gradually reduced from the outermost layer downward in the thickness direction and inward in the width direction.

According to this method, the second protective layer 7 formed on the upper surfaces of the terminal portions 10 of the conductive pattern 6 is thereafter removed by etching or the like, and the notches 23 are formed by etching or perforation while the metal supporting board 2 is contoured into a desired shape as shown in FIG. 1, thereby obtaining the suspension board with circuit 1.

The process of packaging the magnetic head 21 on the suspension board with circuit 1 thus obtained and mounting the suspension board with circuit 1 on the hard disk drive is now schematically described.

First, as shown in FIG. 5, the gimbal section 18 of the obtained suspension board with circuit 1 is folded. More specifically, the gimbal section 18 is folded along the folding section 19 of the suspension board with circuit 1 shown in FIG. 1. In other words, the gimbal section 18 is so folded that the side of the metal supporting board 2 is located upward on the folding section 19.

Then, the suspension board with circuit 1 is mounted on a loading beam 30. The loading beam 30 is used for supporting the suspension board with circuit 1, and the portion of the suspension board with circuit 1 other than the gimbal section 18 is stuck to the loading beam 30 in this mounting.

The magnetic head 21 may be packaged on the packaging region 17 (see FIG. 1) after the aforementioned folding, or before the aforementioned folding.

In order to package the magnetic head 21, the magnetic-head-side connecting terminal portions 10A (see FIG. 1) and terminal portions of the magnetic head 21 are electrically connected with one another. Further, the external-side connecting terminal portions 10B and terminal portions (not shown) of the read/write board are electrically connected with one another, along with the connection of the magnetic-head-side connecting terminal portions 10A.

Then, the suspension board with circuit 1 is mounted on the hard disk drive. In this mounting on the hard disk drive, the magnetic head 21 is opposed to the magnetic disk 22 relatively rotating with respect to the magnetic head 21 at a small interval (e.g., 5 to 10 nm).

Thus, the magnetic head 21 reads data from the magnetic disk 22, and writes data in the magnetic disk 22.

In the suspension board with circuit 1, transmission loss of the conductive pattern 6, i.e., transmission loss of read and write signals between the magnetic head 21 and the read/write board can be reduced due to the simple layer structure obtained by interposing the metal foil 3 between the metal supporting board 2 and the conductive pattern 6.

Further, the first protective layer 4 and the second protective layer 7 are made of tin or a tin alloy, whereby the folding angle of the folding section 19 can be maintained, and the position of the gimbal section 18 once folded can be maintained constant. Therefore, the magnetic head 21 can stably read data from the magnetic disk 22, and can stably write data in the magnetic disk 22.

Further, the first protective layer 4 is interposed between the insulating base layer 5 and the metal foil 3, whereby occurrence of such an ion migration phenomenon that the metal forming the metal foil 3 migrates to the insulating base layer 5 can be reliably prevented.

In addition, the second protective layer 7 is interposed between the insulating cover layer 8 and the conductive pattern 8, whereby occurrence of such an ion migration phenomenon that the conductor forming the conductive pattern 6 migrates to the insulating cover layer 8 can be reliably prevented.

While tin forming the first tin layer 13 is entirely substituted by the tin alloy and the first tin layer 13 disappears in the aforementioned step shown in FIG. 3(d), tin forming the first tin layer 13 may not be entirely substituted by the tin alloy but may be partially remain in the outermost layer of the first protective layer 4 as pure tin.

While tin forming the second tin layer 14 is entirely substituted by the tin alloy and the second tin layer 14 disappears in the aforementioned step shown in FIG. 4(g), tin forming the second tin layer 14 may not be entirely substituted by the tin alloy but may be partially remain in the outermost layer of the second protective layer 7 as pure tin.

In the aforementioned step shown in FIG. 3(d), the first protective layer 4 is formed through the heat treatment for drying or curing in the formation of the insulating base layer 5. Alternatively, the first protective layer 4 made of a tin alloy can be formed by preliminarily forming synthetic resin into a film in the aforementioned pattern, sticking this film onto the metal supporting board 2 including the first tin layer 13 for forming the insulating base layer 5 and thereafter heating the suspension board with circuit 1 for diffusing tin into the metal forming the metal foil 3, for example, though not shown.

Preferably, the first protective layer 4 made of a tin alloy is formed through the heat treatment for drying or curing. Thus, drying or curing in the formation of the insulating base layer 5 and diffusion of tin into the metal forming the metal foil 3 in the formation of the first protective layer 4 can be simultaneously carried out, and the manufacturing steps can be simplified.

In the aforementioned step shown in FIG. 4(g), the second protective layer 7 is formed through the heat treatment for drying or curing in the formation of the insulating cover layer 8. Alternatively, the second protective layer 7 made of a tin alloy can be formed by preliminarily forming synthetic resin into a film in the aforementioned pattern, sticking this film onto the insulating base layer 5 including the second tin layer 14 for forming the insulating cover layer 8 and thereafter heating the suspension board with circuit 1 for diffusing tin into the conductor forming the conductive pattern 6, for example, though not shown.

Preferably, the second protective layer 7 made of a tin alloy is formed through the heat treatment for drying or curing. Thus, drying or curing in the formation of the insulating cover layer 8 and diffusion of tin into the conductor forming the conductive pattern 6 in the formation of the second protective layer 7 can be simultaneously carried out, and the manufacturing steps can be simplified.

While the first protective layer 4 and the second protective layer 7 are formed through the two heat treatments in the formation of the insulating base layer 5 and the insulating cover layer 8 in the above description as shown in FIGS. 3(d) and 4(g), the first protective layer 4 and the second protective layer 7 can alternatively be simultaneously formed through a single heat treatment in the insulating cover layer 8, for example, though not shown.

In order to simultaneously form the first protective layer 4 and the second protective layer 7 through a single heat treatment, a film of synthetic resin, for example, is stuck onto the metal supporting board 2 including the first tin layer 13 for forming the insulating base layer 5 (see FIG. 3(d)). Then, the second metal thin film 12 and the conductive pattern 6 are formed on the insulating base layer 5 (see FIG. 4(e)), the second tin layer 14 is thereafter formed on the surface of the conductive pattern 6 (see FIG. 4(f)), and a varnish of synthetic resin is thereafter coated, dried, exposed to light and developed, and cured as necessary. The first protective layer 4 and the second protective layer 7 are simultaneously formed through the heat treatment for this drying or curing (see FIG. 4(g)). In other words, diffusion of tin into the metal foil 3 and diffusion of tin into the conductive pattern 6 are simultaneously caused by the heat treatment in the formation of the insulating cover layer 8.

While the first metal thin film 11 is interposed between the metal foil 3 and the metal supporting board 2 in the above description, the metal foil 3 can alternatively be directly formed on the metal supporting board 2 without providing the first metal thin film 11, for example, though not shown.

In this case, the metal foil 3 is formed by the subtractive method. In the subtractive method, a conductive layer is laminated on the entire surface of the metal supporting board 2 through a well-known adhesive layer, and an etching resist is formed on the surface of the conductive layer in the same pattern as the aforementioned one. Then, the conductive layer exposed through the etching resist is etched, and the etching resist is thereafter removed.

Preferably, the first metal thin film 11 is interposed between the metal foil 3 and the metal supporting board 2. Thus, the adhesiveness between the metal foil 3 and the metal supporting board 2 can be improved.

While the second metal thin film 12 is interposed between the conductive pattern 6 and the insulating base layer 5 in the above description, the conductive pattern 6 can alternatively be directly formed on the insulating base insulating base layer 5 without providing the second metal thin film 12, for example, though not shown.

In this case, the conductive pattern 6 is formed by the subtractive method, similarly to the above.

Preferably, the second metal thin film 12 is interposed between the conductive pattern 6 and the insulating base layer 5. Thus, the adhesiveness between the conductive pattern 6 and the insulating base layer 5 can be improved.

While the first metal thin film 11 is directly formed on the metal supporting board 2 in the above description, a lower insulating base layer 20 serving as a second insulating base layer can also be interposed between the first metal thin film 11 and the metal supporting board 2 as shown in FIG. 6, for example.

The lower insulating base layer 20 is formed on the surface of the metal supporting board 2 to oppose to at least the metal thin film 11 in the thickness direction so that both width-directional ends thereof are exposed through the metal thin film 11.

An insulator similar to that described above with reference to the insulating base layer 5 is used to form the lower insulating base layer 20. The thickness of the lower insulating base layer 20 is in the range of, e.g., 0.5 to 10 μm, or preferably 2 to 4 μm.

In order to manufacture this suspension board with circuit 1, the metal supporting board 2 is first prepared as shown in FIG. 3(a), and the lower insulating layer 20 is formed in the aforementioned pattern by a method similar to that for forming the insulating base layer 5, though not shown. Then, the first metal thin film 11 and the metal foil 3 are formed on the lower insulating base layer 20 as FIG. 3(b) is referred to, and the first tin layer 13 is formed on the surface of the metal foil 3 as FIG. 3(c) is referred to. Then, the insulating base layer 5 as well as the first protective layer 4 are formed as FIG. 3(d) is referred to, and the second metal thin film 12 and the conductive pattern 6 are formed on the insulating base layer 5 in the aforementioned wired circuit pattern, as FIG. 4(e) is referred to. Then, as shown in FIG. 4(f), the second tin layer 14 is formed on the conductive pattern 6, and the insulating cover layer 8 as well as the second protective layer 7 are formed.

Thus, the adhesiveness between the first metal thin film 11 and the metal supporting board 2 can be improved due to the lower insulating base layer 20 interposed between the first metal thin film 11 and the metal supporting board 2.

### EXAMPLES

The present invention is described more specifically by showing the examples and the comparative examples herein below. However, the present invention is by no means limited to the examples and the comparative examples.

### Example 1

First, a metal supporting board of stainless steel having a thickness of 25 μm was prepared (see FIG. 3(a)), and a first metal thin film was formed by successively forming a thin chromium film having a thickness of 50 nm and a thin copper film having a thickness of 100 nm on the entire surface of the metal supporting board by sputtering. Then, a plating resist was formed on the upper surface of the first metal thin film in a pattern reverse to the pattern of a metal foil, and a copper foil having a thickness of 3 μm was thereafter formed by electrolytic copper plating (see FIG. 3(b)). Then, a first tin layer having a thickness of 0.4 μm was formed on the upper surface, both width-directional side surfaces and both longitudinal side surfaces of the copper foil by electroless tin plating (see FIG. 3(c)).

Then, a varnish of photosensitive polyamic acid resin was applied to the entire upper surface of the metal supporting board including the first tin layer, and heated and dried at 90° C. for 15 minutes. Then, the varnish was exposed to light and developed, and thereafter heated at 370° C. for 120 minutes under decompression to be cured (imidized), while a first protective layer made of a tin-copper alloy in which tin was diffused into copper was formed (see FIG. 3(d)). The thickness of the first protective layer was 1 μm. This thickness of the first protective layer was measured by TOF-SIMS.

Then, a second metal thin film was formed by successively forming a thin chromium film having a thickness of 50 nm and a thin copper film having a thickness of 100 nm on the entire upper surface of the insulating base layer by sputtering. Then, a plating resist was formed on the upper surface of the second metal thin film in a pattern reverse to a conductive pattern, and the conductive pattern of copper having a thickness of 10 μm was thereafter formed by electrolytic copper plating (see FIG. 4(e)).

Then, a second tin layer having a thickness of 0.4 μm was formed on the upper surface and both width-directional side surfaces of the conductive pattern by electroless tin plating (see FIG. 4(f)).

Then, a varnish of photosensitive polyamic acid resin was applied to the entire upper surface of the insulating base layer including the second tin layer, and heated dried at 90° C. for 15 minutes. Then, the varnish was exposed to light and developed, and thereafter heated at 370° C. for 120 minutes under decompression to be cured (imidized), while a second protective layer made of a tin-copper alloy in which tin was diffused into copper was formed (see FIG. 4(g)). The thickness of the second protective layer was 1 μm. This thickness of the second protective layer was measured by TOF-SIMS.

Then, the second protective layer formed on the upper surfaces of terminal portions was removed by etching, and notches were formed, thereby obtaining a suspension board with circuit (see FIG. 1).

### Example 2

A suspension board with circuit was obtained in the same manner as in EXAMPLE 1, except that the thickness of the first tin layer (see FIG. 3(c)) was changed to 0.3 μm and the thickness of the second tin layer (see FIG. 4(f) was also changed to 0.3 μm. The thickness of the first protective layer was 0.8 μm, and the thickness of the second protective layer was also 0.8 μm.

### Example 3

A suspension board with circuit was obtained in the same manner as in EXAMPLE 1, except that a lower insulating base layer was interposed between the metal thin film and the metal supporting board (see FIG. 6).

In other words, a varnish of photosensitive polyamic acid resin was applied to the entire surface of the metal supporting board, heated and dried at 90° C. for 15 minutes, exposed to light and developed, and thereafter heated and cured (imidized) at 370° C. for 120 minutes under decompression, thereby forming the lower insulating base layer having a thickness of 3 μm. Then, a thin chromium film having a thickness of 50 nm and a thin copper film having a thickness of 100 nm were successively formed on the entire surface of the metal supporting board including the lower insulating base layer, thereby forming the first metal thin film.

### Comparative Example 1

A suspension board with circuit was obtained in the same manner as in EXAMPLE 1, except that the second tin layer was not formed. In other words, the insulating cover layer was directly formed on the surface of the conductive pattern without forming the second protective layer.

### Comparative Example 2

A suspension board with circuit was obtained in the same manner as in EXAMPLE 1, except that the first tin layer was not formed. In other words, the insulating base layer was directly formed on the surface of the metal foil without forming the first protective layer.

### Comparative Example 3

A suspension board with circuit was obtained in the same manner as in EXAMPLE 1, except that the first tin layer and the second tin layer were not formed. In other words, the insulating base layer was directly formed on the surface of the metal foil and the insulating cover layer was directly formed on the surface of the conductive pattern without forming the first and second protective layers.

### Evaluation

(1) Transmission Efficiency

In each of the suspension boards with circuit obtained in the examples and the comparative examples, an output signal intensity (Pₒᵤₜ) and an input signal intensity (Pᵢₙ) were measured and the transmission efficiency was evaluated as the ratio of the output signal intensity to the input signal intensity given by Formula (1) shown below. The result of the evaluation is shown in Table 1.

Transmission Efficiency (%)=Pₒᵤₜ/Pᵢₙ (1)

TABLE 1

| | | EXAMPLE | | | COMPARATIVE EXAMPLE | | |
|---|---|---|---|---|---|---|---|
| | | EXAMPLE | EXAMPLE | EXAMPLE | COMPARATIVE | COMPARATIVE | COMPARATIVE |
| | | 1 | 2 | 3 | EXAMPLE 1 | EXAMPLE 2 | EXAMPLE 3 |
| FIRST | PRESENCE/ | PRESENT | PRESENT | PRESENT | PRESENT | ABSENT | ABSENT |
| PROTECTIVE | ABSENCE | | | | | | |
| LAYER | THICKNESS(μm) | 1.0 | 0.8 | 1.0 | 1.0 | — | — |
| SECOND | PRESENCE/ | PRESENT | PRESENT | PRESENT | ABSENT | PRESENT | ABSENT |
| PROTECTIVE | ABSENCE | | | | | | |
| LAYER | THICKNESS(μm) | 1.0 | 0.8 | 1.0 | — | 1.0 | — |
| EVALUATION | TRANSMISSION | 79.0 | 79.1 | 80.0 | 78.9 | 78.5 | 80.0 |
| | EFFICIENCY | | | | | | |
| | (Pₒᵤₜ/Pᵢₙ) | | | | | | |
| | (%) | | | | | | |

(2) Shape Retention

As to each of the suspension boards with circuit obtained in EXAMPLE 1 and COMPARATIVE EXAMPLE 3, a creep strain and a strain relaxation were measured with Ficherscope NH 2000 (universal testing machine by Ficher) by folding the gimbal section along the folding section. The results of the creep strain and the strain relaxation are shown in FIGS. 7 and 8 respectively.

It is understood from FIGS. 7 and 8 that the suspension board with circuit according to EXAMPLE 1 provided with the first and second protective layers exhibit smaller changes in the creep strain and the strain relaxation as compared with the suspension board with circuit according to COMPARATIVE EXAMPLE 3 not provided with the first and second protective layers. Thus, it is understood that the suspension board with circuit according to EXAMPLE 1 has higher shape retention after folding as compared with the suspension board with circuit according to COMPARATIVE EXAMPLE 3.

While the illustrative embodiments of the present invention are provided in the above description, such is for illustrative purpose only and it is not to be construed limitative. Modification and variation of the present invention that will be obvious to those skilled in the art is to be covered by the following claims.

What is claimed is:

1. A wired circuit board comprising:
a metal supporting board;
a metal foil formed on the metal supporting board;
a first protecting layer formed on the surface of the metal foil, the first protecting layer is made of tin or a tin alloy;
a first insulating layer formed on the metal supporting board to cover the first protecting layer;
a conductive pattern formed on the insulating layer; and
a second protecting layer formed on the surface of the conductive pattern, the second protecting layer is made of tin or a tin alloy.

2. The wired circuit board according to claim 1, wherein
the metal foil and the conductive layer are formed of copper, and the first protecting layer and the second protecting layer are formed of a tin-copper alloy which is formed by diffusing tin into copper.

3. The wired circuit board according to claim 1, wherein each thickness of the first protecting layer and the second protecting layer is not less than 0.05 μm.

4. The wired circuit board according to claim 1, further comprising a second insulating layer that is interposed between the metal supporting board and the metal foil.

5. The wired circuit board according to claim 1, wherein the wired circuit board is used as a suspension board with circuit.
